(19) United States
(12) Patent Application Publication
(10) Pub. No.: US 2014/0048867 A1
(43) Pub. Date: Feb. 20, 2014

(54) MULTI-TIME PROGRAMMABLE MEMORY

(71) Applicants: Eng Huat TOH, Singapore (SG); Shyue Seng TAN, Singapore (SG); Khee Yong LIM, Singapore (SG); Elgin QUEK, Singapore (SG)

(72) Inventors: Eng Huat TOH, Singapore (SG); Shyue Seng TAN, Singapore (SG); Khee Yong LIM, Singapore (SG); Elgin QUEK, Singapore (SG)

(73) Assignee: GLOBALFOUNDRIES SINGAPORE PTE. LTD., Singapore (SG)

(21) Appl. No.: 13/589,176

(22) Filed: Aug. 20, 2012

(51) Int. Cl. H01L 29/792; H01L 21/336

(52) U.S. Cl. 257/324; 438/287; 257/E29.309; 257/E21.423

(57) ABSTRACT

A device is disclosed. The device includes a substrate and a fin structure disposed on the substrate. The fin structure serves as a common body of n transistors. The transistors include separate charge storage layers and gate dielectric layers. The charge storage layers are disposed over a top surface of the fin structure and the gate dielectric layers are disposed on sidewalls of the fin structure. n=2^{x}, x is a whole number greater or equal to 1. A transistor can interchange between a select transistor and a storage transistor.

### BACKGROUND

Non-volatile memory (NVM) circuits, for example, one-time programmable (OTP) NVM, have achieved widespread adoptions for code and data storage applications. However, many of the NVM use floating gate as storage medium and can only be programmed once. Therefore, no device update is possible. Moreover, the cell size is limited by gate-to-gate limitation and overlay tolerance. This, in turn, puts a restriction on select gate (SG) drive current and minimal usable gate length.

Therefore, it is desirable to provide a highly scalable device which can be updated multi-times.

### SUMMARY

A device is disclosed. The device includes a substrate and a fin structure disposed on the substrate. The fin structure serves as a common body of n transistors. The transistors include separate charge storage layers and gate dielectric layers. The charge storage layers are disposed over a top surface of the fin structure and the gate dielectric layers are disposed on sidewalls of the fin structure. n=2^{x}, x is a whole number greater or equal to 1. A transistor can interchange between a select transistor and a storage transistor.

In another embodiment, a method of forming a device is presented. The method includes providing a substrate and forming a fin structure disposed on the substrate. The fin structure serves as a common body of n transistors. The transistors include separate charge storage layers and gate dielectric layers. The charge storage layers are disposed over a top surface of the fin structure and the gate dielectric layers are disposed on sidewalls of the fin structure. n=2x, x is a whole number greater or equal to 1. A transistor can interchange between a select transistor and a storage transistor.

In yet another embodiment, a multi-bit device is disclosed. The multi-bit device includes a substrate and a fin structure disposed on the substrate. The fin structure serves as a common body of n transistors which are coupled in series between first and second cell terminals. The transistors include separate charge storage layers and gate dielectric layers. The charge storage layers are disposed over a top surface of the fin structure and the gate dielectric layers are disposed on sidewalls of the fin structure. n=2x, x is a whole number greater or equal to 1. A transistor can interchange between a select transistor and a storage transistor. A transistor comprises first and second source/drain terminals. First source/drain terminal of the first transistor is coupled to the first cell terminal. Second source/drain terminal of the last transistor is coupled to the second cell terminal. Second source/drain terminal and first source/drain terminal of adjacent transistors form a common source/drain region in the fin structure.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following

FIGS. 1a-b show top and isometric view of an embodiment of a memory cell;

FIGS. 1c-d show top and isometric view of another embodiment of a memory cell;

FIG. 2 shows an embodiment of a memory cell;

FIGS. 3 and 4 show different memory operations of a memory cell;

FIGS. 5a-b show top and isometric view of an embodiment of a memory cell;

FIGS. 5c-d show top and isometric view of another embodiment of a memory cell;

FIG. 6 shows an embodiment of a memory cell;

FIGS. 7a-e show cross-sectional views of an embodiment of a process for forming a device or IC;

FIGS. 8a-b show cross-sectional views of another embodiment of a process for forming a device or IC; and

FIGS. 9a-b show cross-sectional view of another embodiment of a process for forming a device or IC.

### DETAILED DESCRIPTION

Embodiments generally relate to semiconductor devices. More particularly, some embodiments relate to memory devices, such as non-volatile memory (NVM) devices. Such memory devices, for example, can be incorporated into standalone memory devices, such as USB or other types of portable storage units, or ICs, such as microcontrollers or system on chips (SoCs). The devices or ICs can be incorporated into or used with, for example, consumer electronic products, or relate to other types of devices.

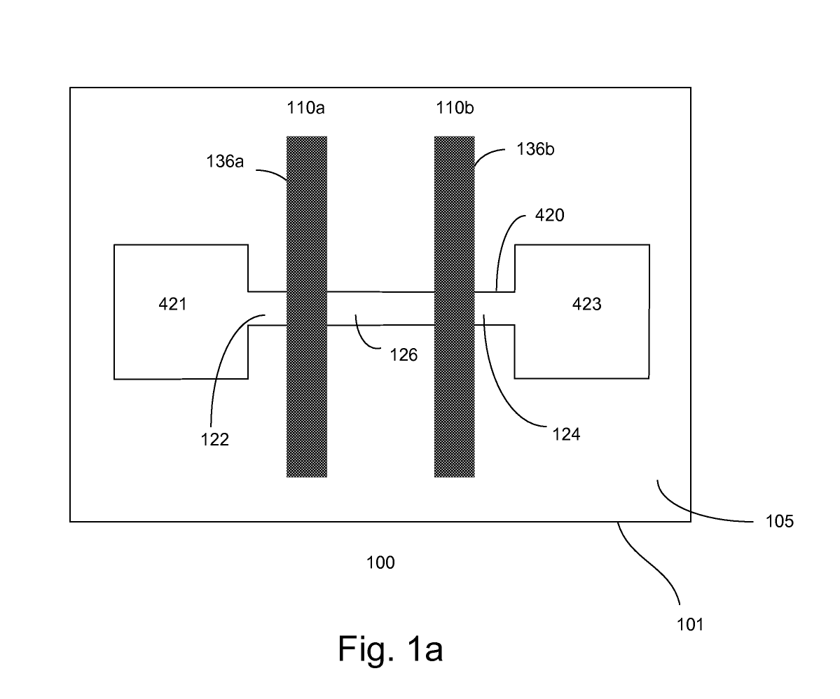

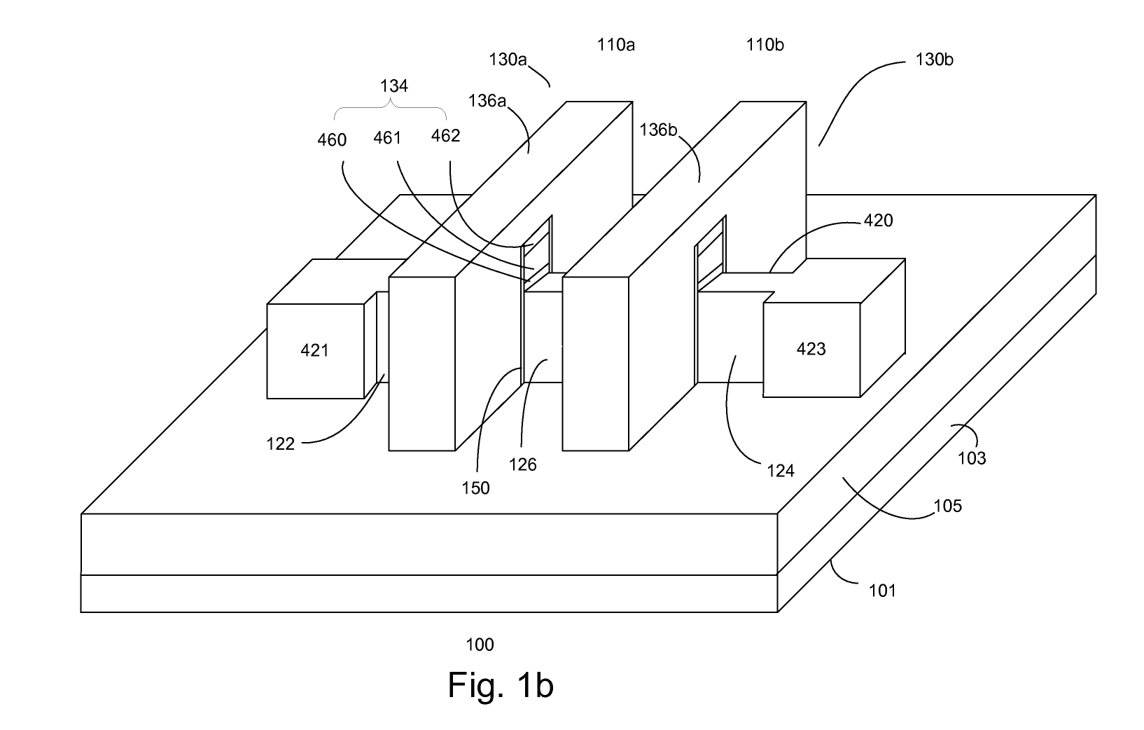

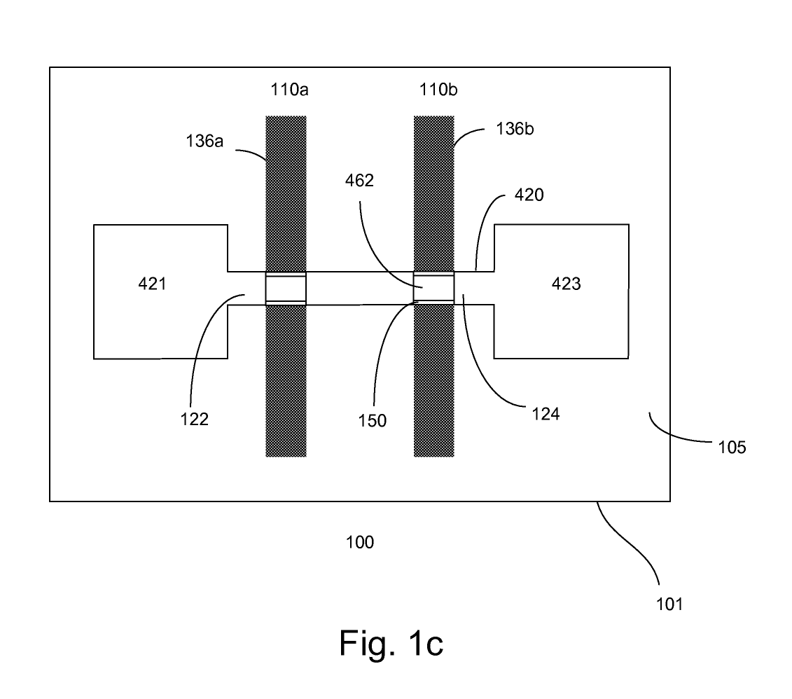

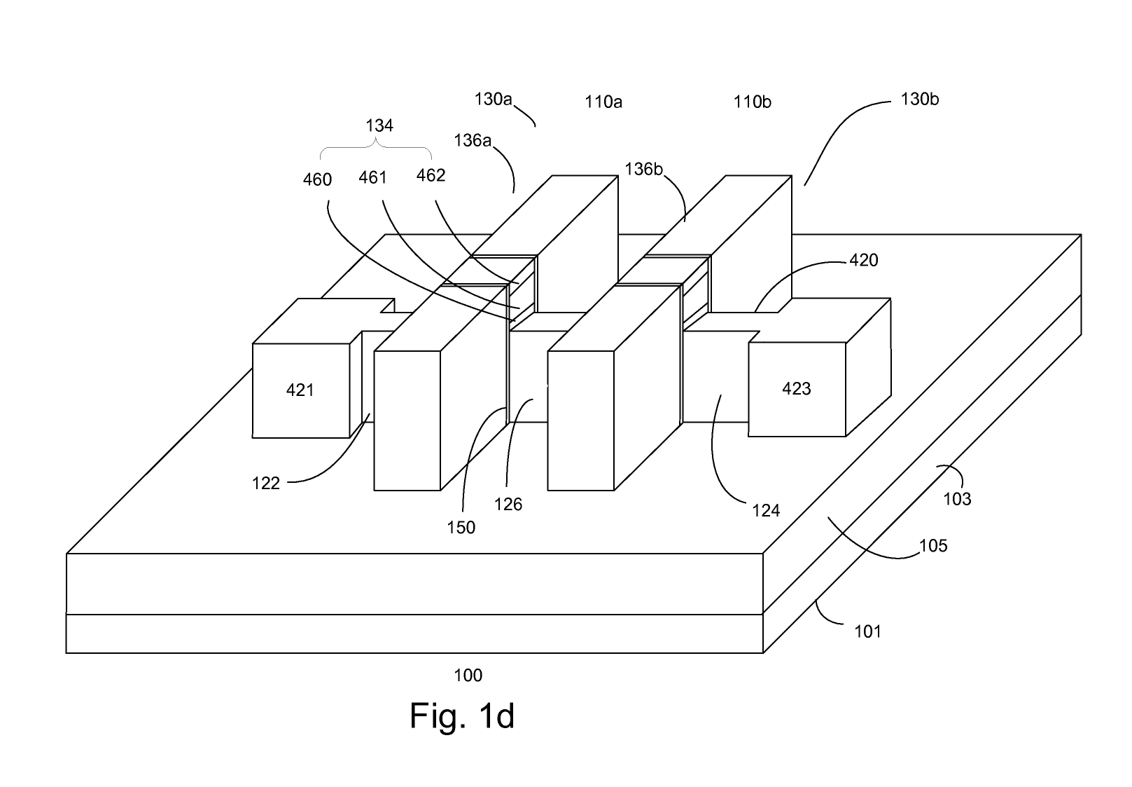

FIGS. 1a-b show various views of an embodiment of a memory cell 100. FIG. 1a shows a top view while FIG. 1b shows an isometric view of an embodiment of a memory cell of FIG. 1a. The memory cell, for example, is a part of a memory device. In other embodiment, the memory cell is a part of an IC device. In one embodiment, the memory cell is a multi-bit memory cell. A dual-bit memory cell is capable of storing two bits of data. In one embodiment, the memory cell is a dual-bit multi-time programmable (MTP) non-volatile memory (NVM) cell. The dual-bit memory cell may be configured as a NOR-type memory cell. Providing other types of multi-bit memory cell configurations or storing other number of bits may also be useful.

The memory cell is formed on a substrate 101. In one embodiment, the substrate is a semiconductor-on-insulator substrate. A semiconductor-on-insulator substrate includes a surface semiconductor layer separated from a crystalline bulk 103 by an insulator layer 105. The insulator layer, for example, may be a dielectric insulating material. The insulator layer, for example, is formed from silicon oxide, providing a buried oxide (BOX) layer. Other types of dielectric insulating materials may also be useful. The silicon-on-insulator substrate, for example, is a silicon-on-insulator (SOI) substrate. For example, the surface and bulk crystalline layers are single crystalline silicon. Other types of substrates, such as silicon-germanium (SiGe), germanium (Ge), gallium-arsenic (GaAs) or any other suitable semiconductor materials may also be useful for the semiconductor-on-insulator substrate. It is understood that the surface and bulk layers need not be the same material.

The substrate can be a lightly doped substrate. In one embodiment, at least the surface semiconductor layer is lightly doped. In one embodiment, the surface layer is lightly doped with p-type dopants. Providing other types of doped surface layers may also be useful. For example, the surface layer may be doped with n-type dopants and/or other dopant concentrations, including intrinsically doped, may also be used. Providing a bulk with a doped surface layer may also be useful.

In other embodiments, the substrate may be a bulk semiconductor substrate. For example, the bulk substrate is not a semiconductor-on-insulator substrate. The bulk substrate, for example, may be a silicon substrate. Alternatively, the substrate may be formed of other semiconductor materials, such as SiGe, Ge or GaAS. In one embodiment, the substrate is a lightly doped substrate. The substrate may be lightly doped with p-type dopants. Providing other types of substrates may also be useful. For example, the substrate may be doped with n-type dopants and/or other dopant concentrations, including intrinsically doped, may also be used.

In one embodiment, the transistors 110a-b of the memory cell is fin-type transistors. For example, the transistors are fin field effect transistors (FinFETs). Other types of transistors may also be useful. The FinFETs include a common fin structure 420 disposed on the substrate. The fin structure, in one embodiment, is formed from the semiconductor substrate. In the case of a semiconductor-on-insulator substrate, the fin structure is formed of the surface layer of the substrate. For example, a bottom of the fin structure is disposed on the top of the BOX of the semiconductor-on-insulator layer. The thickness of the surface layer, for example, defines a height of the fin structure. Alternatively, the fin structure is formed from a surface portion of a bulk semiconductor substrate. In such cases, the fin is an integral part of the bulk substrate. A dielectric layer may be provided over a top of the bulk at the bottom of the fin structure. The dielectric layer covers a lower portion of the fin structure and isolates the memory cell from other memory cells. The top of the dielectric layer, for example, defines a height of the fin structure.

The fin structure serves as the body of the transistors. The fin structure is an elongated structure. The fin structure, for example, is along a first or x direction. The height of the fin structure, for example, may be about 5-100 nm. Other fin heights may also be useful. The width of the fin structure may be about 5-100 nm. The width, for example, may depend on the fin height, process capability and total transistor width requirements. Other fin thicknesses may also be useful. In some cases, the width of the fin structure may be included in determining the channel width of the device. Other dimensions for the fin structure may also be useful. The dimensions of the fin structure, for example, may depend on device or design requirements.

The fin may be doped with second polarity type dopants. For example, the fin may be undoped or lightly doped with second polarity type dopants. In one embodiment, the dopant concentration of the fin is about 10¹⁵-10¹⁸cm⁻³. The doped fin forms channels of the transistors below the gate.

In one embodiment, first and second gates 130a-b are provided on the substrate in contact with the fin structure. The first and second gates include first and second gate electrodes 136a-b. The gate electrodes, for example, comprise elongated members. The gate electrodes, in one embodiment, traverse the fin structure in a second or y direction. In one embodiment, the second direction is orthogonal to the first direction. Providing gate electrodes which traverse the fin structure at other angles may also be useful. The gate electrodes, as shown, completely wrap around the fin. Providing a gate electrode which wraps around the fin structure forms a transistor with a single gate. The gate electrodes, in one embodiment, comprise a semiconductor material. For example, the gate electrodes comprise polysilicon. Other types of materials may also be used to form the gate. For example, the gates comprise metal gates, such as TaN or TiN. Furthermore, the gate electrodes may be doped with dopants to reduce resistance and poly depletion. Depending on design requirements, the gate is appropriately doped with the dopant type and concentration. For example, the dopant type may either be the same or opposite type as the S/D regions.

In one embodiment, a charge storage dielectric layer 134 is disposed on a top surface of the fin structure, separating upper portions of a gate electrode (e.g., above the top surface of the fin structure) from the top of the fin structure. For example, a first charge storage dielectric layer is disposed on the top surface of the fin structure under the first gate electrode and a second charge storage dielectric layer is disposed on the top surface of the fin structure to provide separation between the top surface of the fin structure and the second gate electrode. The charge storage dielectric layers 134 are capable of storing charge corresponding to the bits of the memory cell. In one embodiment, a charge storage dielectric layer is a composite charge storage layers or stack. The charge storage stack, for example, includes an oxide-nitride-oxide (ONO) sandwich 460, 461 and 462. In one embodiment, the oxide layer 462 serves as a blocking oxide, the oxide layer 460 serves as a tunneling oxide, and the nitride layer 461 sandwiched between the two oxide layers serves as a charge storage layer to store charges. Other types of charge storage dielectric layers or stacks may also be useful. For example, a charge storage dielectric layer may include storage dielectric stacks such as an oxide/a-Si/oxide, an oxide/nanocrystal/oxide, an oxide/nitride/Al₂O₃, a nanocrystal embedded in oxide or an oxide-metal (high-K)-oxide stack. Other configuration of charge storage dielectric layers may also be useful. For example, multiple storage stacks may also be useful to serve as a storage layer. The charge storage dielectric layer facilitates a gate to be a MC.

In one embodiment, at least the sides of the nitride layer 461 of the charge storage dielectric stack layer along the length of the fin structure are protected by a storage protection layer. The storage protection layer, for example, may be oxide or silicon oxynitride. Other types of protection layer may also be useful.

In one embodiment, a gate dielectric layer 150 is disposed on sidewalls of the fin structure under a gate electrode. In some embodiment, the gate dielectric layer may also serve as the storage protection layer which covers the sides of the charge storage dielectric layers. Other configurations of storage protection layers and gate dielectric layers may also be useful. The gate dielectric layer separates lower portions of a gate (e.g., below the top surface of the fin structure) from the fin structure. For example, a first gate dielectric layer is provided on sidewalls of the fin structure to separate lower portions of the first gate electrode from the fin structure and a second gate dielectric layer is provided on sidewalls of the fin structure to separate lower portions of the second gate electrode from the fin structure. The gate dielectric layer may be, for example, silicon oxide. For example, the gate dielectric layer may be HfSiON, SiON or HfO₂ or a combination thereof. Other types of gate dielectric materials may also be useful. The gate dielectric layer facilitates a gate to be a SG.

A transistor includes first and second source/drain (S/D) regions in the fin structure adjacent to a gate. For example, the first transistor includes first and second S/D regions in the fin structure adjacent to the first gate and the second transistor includes first and second S/D regions in the fin structure adjacent to the second gate. As shown, the first S/D region of the first transistor serves as the first cell terminal 122, the second S/D region of the first transistor and first S/D region of the second transistor form a common S/D region 126 of the transistors and the second S/D region of the second transistor serves as the second cell terminal 124.

The S/D regions are doped with first polarity type dopants. In one embodiment, the S/D regions are heavily doped with first polarity type dopants. The dopant concentration of the S/D regions, for example, may be about 10¹⁹-10²⁰ cm⁻³. Other dopant concentrations may also be useful. The first polarity type dopants may be n-type, forming a memory cell with n-type transistors. Alternatively, the first polarity type is p-type for forming a p-type memory cell. P-type dopants can include boron (B), aluminum (Al), indium (In) or a combination thereof, while n-type dopants can include phosphorus (P), arsenic (As), antimony (Sb) or a combination thereof.

First and second contact pads 421 and 423 may be provided at first and second ends of the fin structure. The contact pads provide additional surface area for contacts for coupling to the cell terminals. The contact pads, in one embodiment, are an integral part of the fin structure. For example, the contact pads have the same material as the fin structure and dopants of S/D regions of the transistors. For example, the fin structure is formed with the pad structures and doped at the same time as the S/D regions of the transistors are formed. Other configurations of fin structures, S/D regions and contact pads may also be useful.

In some embodiments, the S/D regions may be provided with lightly doped S/D extension regions. In some embodiments, the S/D extension profile may extend beneath the gate. Providing S/D extensions improves short channel effect. To facilitate forming S/D extension regions, gate sidewall spacers (not shown) may be provided. The gate sidewall spacers may be formed from a dielectric material, such as silicon oxide. Other types of spacer materials may also be useful. For example, S/D extensions are formed without the spacers and the main S/D regions are formed with the spacers. Other configurations of S/D extensions, S/D regions and spacers may also be useful.

The gates may be provided with gate contact pads (not shown). In one embodiment, a gate contact pad is provided at an end of a gate. Alternatively, contact pads are provided at ends of the gate. The contact pads provide additional surface area for contacts to couple to control lines. The contact pads, in one embodiment, are an integral part of the gate structure. For example, the contact pads have the same material as the gate. Other configurations of the gates and gate pads may also be useful.

A gate of a transistor may be a single gate. Other configurations of gates may also be useful. In some embodiments, a gate of a transistor may be a dual-gate. For example, a gate may be separated into first and second sub-gates.

FIGS. 1c-d show various views of another embodiment of a memory cell 100. FIG. 1c shows a top view while FIG. 1d shows an isometric view of a memory cell of FIG. 1c. The memory cell, for example, is a part of a memory device. In other embodiment, the memory cell is a part of an IC device. As shown, the memory cell is a dual-bit memory cell which is similar to that described in FIGS. 1a-b. As such, common elements may not be described or described in detail.

The memory cell, as shown, includes gate electrodes 130a-b of the first and second transistors 110a-b which are disposed on first and second sides of the fin structure 420 and not over it. For example, a gate electrode includes first and second sub-gates which are separated by the fin sidewalls, charge storage dielectric layer and gate dielectric layers 150. The sub-gates, for example, have a top surface which is coplanar with a top surface of the charge storage dielectric layer 134. Providing first and second sub-gates allows the sub-gates to be separately biased.

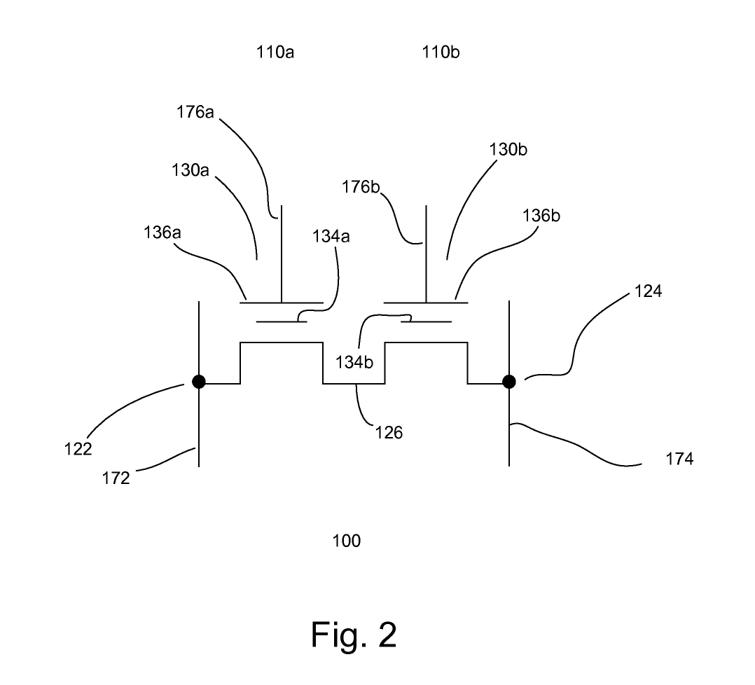

The operations of the memory cells as described in FIGS. 1a-d are illustrated in FIG. 2. The dual-bit memory cell includes first and second transistors 110a-b coupled in series between first and second cell terminals 122 and 124. Providing other number of transistors for other number of multi-bit cells may also be useful.

The first cell terminal is a source terminal and the second cell terminal is a drain terminal. In one embodiment, the first and second cell terminals may serve as select and bitline terminals. In one embodiment, the first cell terminal serves as the select terminal and the second cell terminal serves as the bitline terminal. Other configurations of terminals may also be useful. The select terminal is coupled to a select line (SL) and the bitline terminal is coupled to a bitline (BL). SL and BL can be interchangeable. The gates of the first and second transistors may serve as first and second gate terminals 176a-b of the memory cell. First and second gate lines (GLs) are coupled to the gate terminals of the transistors. A plurality of memory cells may be interconnected by SLs, BLs and GLs to form a memory array.

As described, a gate of a transistor includes both charge storage dielectric layers 134 and gate dielectric layers 150. The charge storage dielectric layers serve as a storage node corresponding to a bit of the memory cell. For example, the first charge storage dielectric layers serve as a first storage node corresponding to a first bit and the second charge storage dielectric layers serve as a second storage node corresponding to the second bit. The charge storage dielectric layers are encompassed by dielectric materials. In one embodiment, the charge storage dielectric layers include a tunnel oxide on top of the fin, and a charge storage layer sandwiched between the tunneling oxide and a blocking oxide. The sandwiched stack is in turn surrounded by a dielectric layer or gate dielectric. The gate dielectric forms at the sides of the fin and possibly at the side of the charge storage dielectric layers. Providing a transistor with a gate which includes both the charge storage dielectric layers and gate dielectric layers enables the transistor to interchange between a select gate (SG) and a control gate (MC). The SG is used to access the memory cell while the MC controls the storage node on top surface of the fin. For example, when the second bit is accessed, the first gate is the SG while the second gate is the MC. On the other hand, when the first bit is accessed, the second gate is the SG and the first gate is the MC.

In one embodiment, the gate line coupled to the SG is referred to as the word line (WL) and the gate line coupled to the MC is referred to as a control line (CL). Since the SG and MC are interchangeable, the WL and CL are also interchangeable. The cell terminal adjacent to the SG serves as the select terminal which is coupled to the SL while the cell terminal adjacent to the control gate serves as the bitline terminal coupled to the BL. As such, like SG and MC, the SL and BL are interchangeable. Providing a memory cell with two gates which are interchangeable between MC and SG advantageously forms a dual-bit transistor with two gates. This facilitates more compact and smaller unit cell sizes.

An access to a bit of the memory cell may include different types of memory access operations. In one embodiment, memory access operations include read, programming and erase operations. Appropriate signals or voltages may be applied to the different terminals of the memory cell, for example, via the SL, BL, CL and WL, to perform the desired memory access operation on the desired bit of the memory cell. Table 1a shows the various signals applied to the terminals of the memory cell, depending on the desired operation and bit to access.

TABLE 1A

| | SG | SG | MC | MC | BL | BL | SL | SL |
|---|---|---|---|---|---|---|---|---|
| Operation | (Sel.) | (Unsel.) | (Sel.) | (Unsel.) | (Sel.) | (Unsel.) | (Sel.) | (Unsel.) |
| Program | Vsel | Vunsel | Vg, pgm | Vunsel | Vd, pgm | Vinhibit | GND | GND |
| Erase | Vsel | Vunsel | Vg, ers | Vunsel | Vd, ers | Vinhibit | GND | GND |
| Read | Vsel | Vunsel | Vg, read | Vunsel | Vd, read | Vinhibit | GND | GND |

Table 1b shows some embodiments of the values for the different signals applied to the terminals of an n-type memory cell and a p-type memory cell.

TABLE 1b

| | n-type cell (V) | p-type cell (V) |
|---|---|---|
| Vsel | 3 | −3 |
| Vunsel | 0 | 0 |
| Vd, pgm | 6 | −6 |
| Vd, ers | 6 | −6 |
| Vd, read | 2 | −2 |
| Vg, pgm | 5 | −5 |
| Vg, ers | −3 | 3 |
| Vg, read | 0 | 0 |
| Vinhibit | 0, float | 0, float |
| Vs | 0 | 0 |

Providing signals of other voltages to the terminals of the memory cell may also be useful. For example, voltages of ±2 V from the exemplary values in table 1b for the signals may also be used.

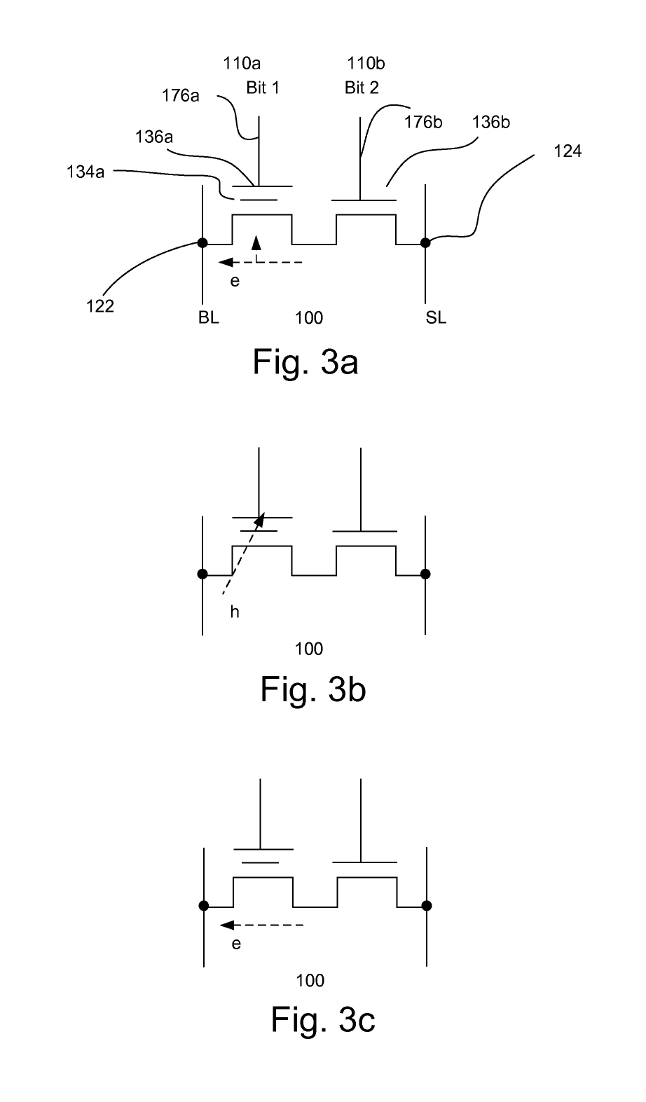

FIGS. 3a-c show schematic diagrams of memory accesses to Bit 1 of the memory cell. As shown, Bit 1 corresponds to the first transistor of the memory cell. When Bit 1 is accessed, the first transistor serves as a MC and the second transistor serves as a SG.

Referring to FIG. 3a, a program operation is depicted. To perform a program operation on Bit 1 of the memory cell, the following signals are applied to the terminals of the memory cell:
first cell terminal (e.g., BL)=Vd,pgm;
second cell terminal (e.g., SL)=Vs;
first gate line (e.g.,CL)=Vg,pgm; and
second gate line (e.g., WL)=Vsel.

The signal Vsel applied to the second gate of the second transistor switches the channel on to access Bit 1 and Vg,pgm applied to the first gate of the first transistor and Vd,pgm to BL result in electrons flowing through the channel from the source to the drain, as indicated by the arrow. An electric field generated is sufficiently high to cause impact-ionization of electron-hole pairs near the drain side and the high energy electrons would be injected across the tunneling oxide onto the charge storage node/layer. This increases the gate threshold voltage.

FIG. 3b shows an erase operation to Bit 1 of the memory cell. To perform an erase operation on Bit 1 of the memory cell, the following signals are applied to the terminals of the memory cell:
first cell terminal (e.g., BL)=Vd,ers;
second cell terminal (e.g., SL)=Vs;
first gate line (e.g., CL)=Vg,ers; and
second gate line (e.g., WL)=Vsel.
   During an erase operation, a large voltage of the opposite polarity is applied between MC and the first cell terminal, for example, the BL, resulting in band-to-band hot hole injection into the charge storage node/layer. This lowers the gate threshold voltage.

Referring to FIG. 3c, a read operation is shown. To perform a read operation on Bit 1 of the memory cell, the following signals are applied to the terminals of the memory cell:
first cell terminal (e.g., BL)=Vd,read;
second cell terminal (e.g., SL)=Vs;
first gate line (e.g., CL)=Vg,read; and
second gate line (e.g., WL)=Vsel.
   When a bit which has been programmed is read, the read current is low due to the higher gate threshold voltage. On the other hand, when a bit which has been erased is read, the read current is high due to the lower gate threshold voltage. In one embodiment, a programmed bit stores a “0” while an erased bit stores a “1”. Providing other configurations of programmed and erased bits may also be useful.

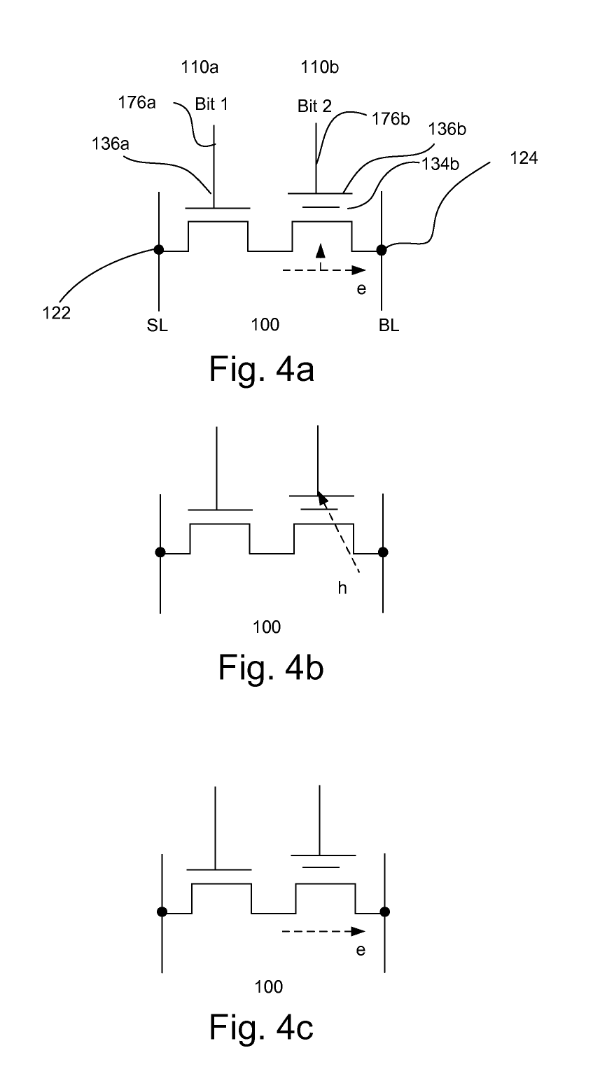

FIGS. 4a-c show schematic diagrams of memory accesses to Bit 2 of the memory cell. As shown, Bit 2 corresponds to the second transistor of the memory cell. When Bit 2 is accessed, the second transistor serves as a MC and the first transistor serves as a SG.

Referring to FIG. 4a, a program operation is depicted. To perform a program operation on Bit 2 of the memory cell, the following signals are applied to the terminals of the memory cell:
first cell terminal (e.g., SL)=Vs;
second cell terminal (e.g., BL)=Vd,pgm;
first gate line (e.g., WL)=Vsel; and
second gate line (e.g., CL)=Vg, pgm.

The signal Vsel applied to the first gate of the first transistor switches the channel on to access Bit 2 and Vg,pgm applied to the second gate of the second transistor and Vd,pgm to BL result in electrons flowing through the channel from the source to the drain, as indicated by the arrow. An electric field generated is sufficiently high to cause impact-ionization of electron-hole pairs near the drain side and the high energy electrons would be injected across the tunneling oxide on to the charge storage node/layer. This increases the gate threshold voltage.

FIG. 4b shows an erase operation to Bit 2 of the memory cell. To perform an erase operation on Bit 2 of the memory cell, the following signals are applied to the terminals of the memory cell:
first cell terminal (e.g., SL)=Vs;
second cell terminal (e.g., BL)=Vd,ers;
first gate line (e.g., WL)=Vsel; and
second gate line (e.g., CL)=Vg,ers.

During an erase operation, a large voltage of the opposite polarity is applied between MC and the second cell terminal, resulting in band-to-band hot hole injection into the charge storage node/layer. This lowers the gate threshold voltage.

Referring to FIG. 4c, a read operation is shown. To perform an read operation on Bit 2 of the memory cell, the following signals are applied to the terminals of the memory cell:
first cell terminal (e.g., SL)=Vs;
second cell terminal (e.g., BL)=Vd,read;
first gate line (e.g., WL)=Vsel; and
second gate line (e.g., CL)=Vg,read.
   In one embodiment, the read current of a program bit is low due the higher gate threshold voltage while that of an erased bit is high due to the lower gate threshold voltage.

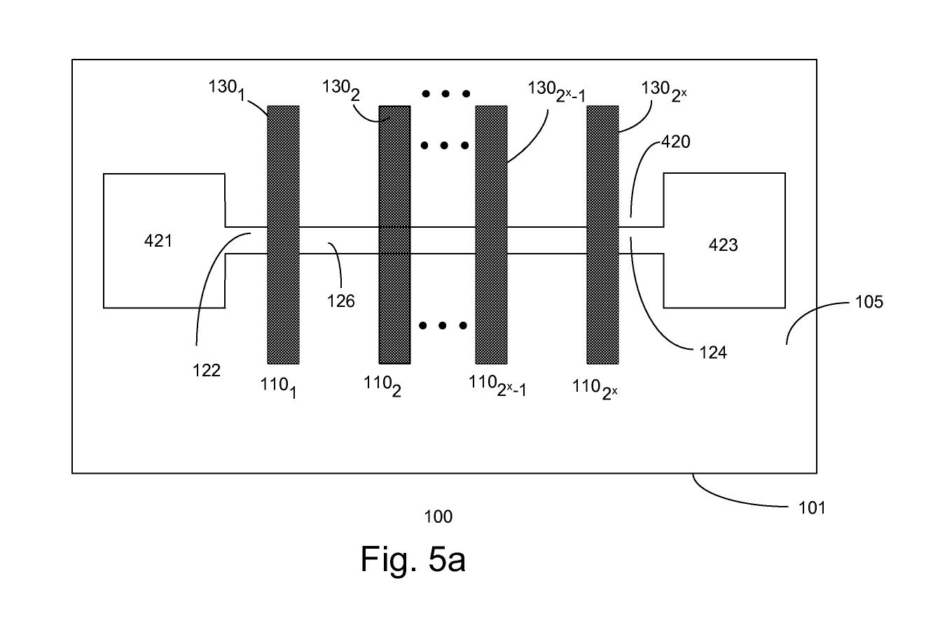

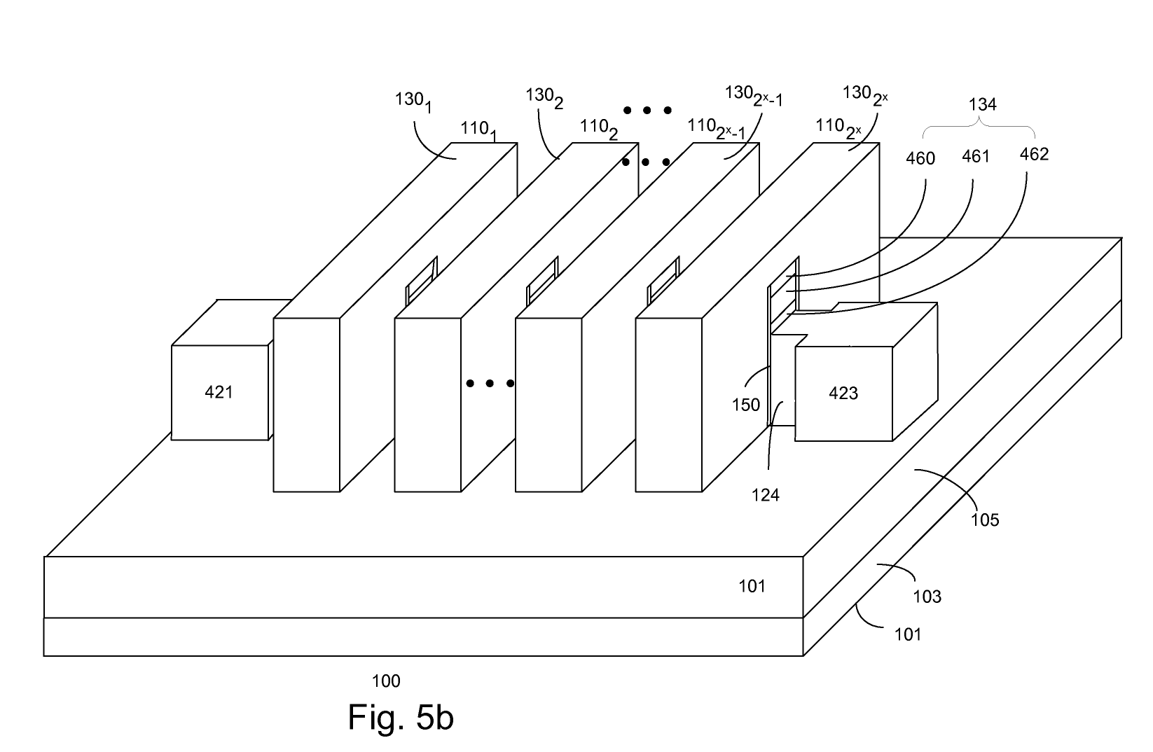

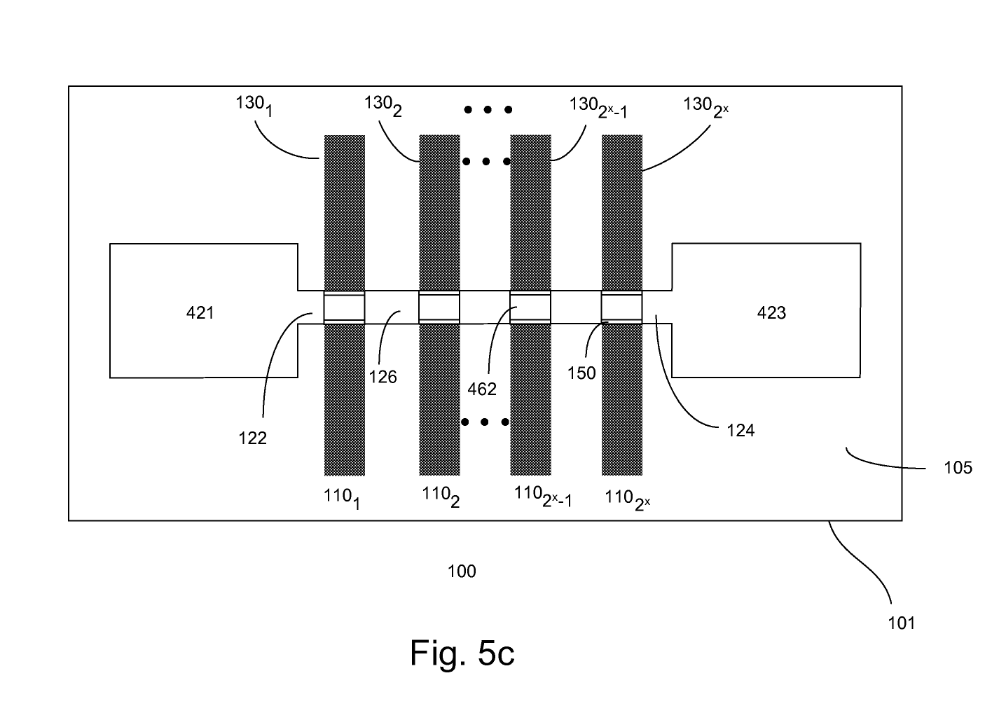

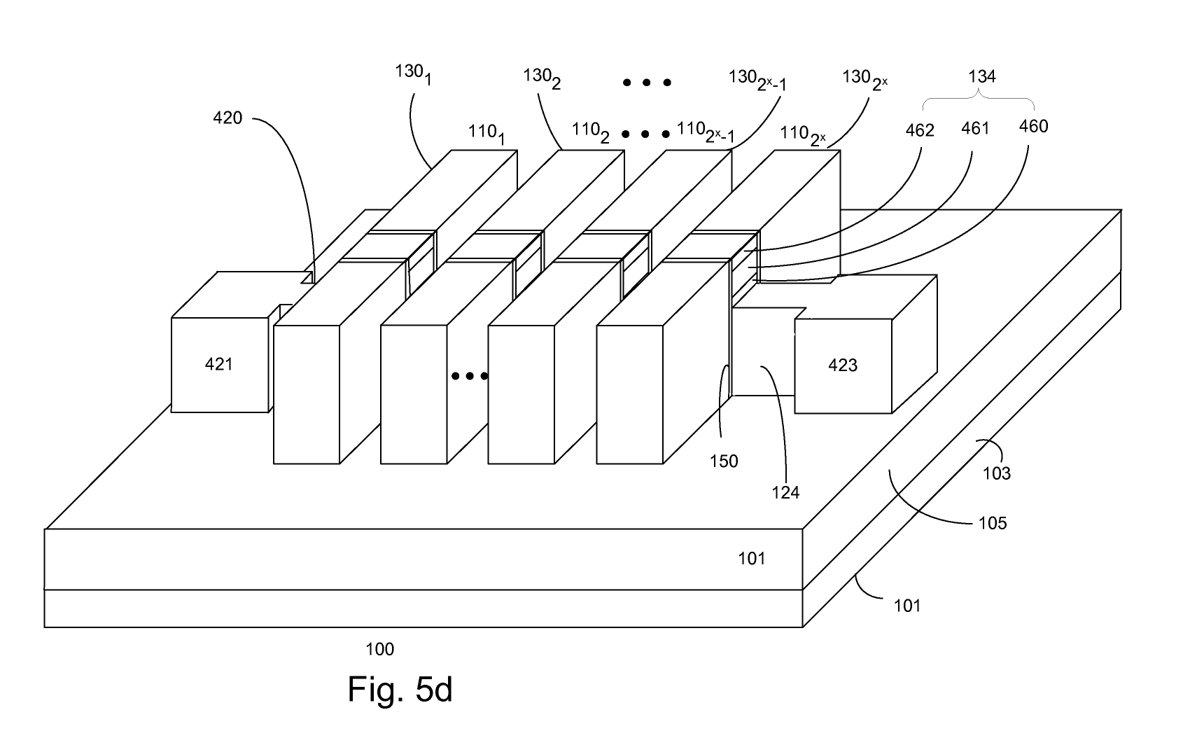

FIGS. 5a-b show various views of another embodiment of a multi-bit memory cell 100. FIG. 5a shows a top view while FIG. 5b shows an isometric view of an embodiment of a memory cell in FIG. 5a. The memory cell, for example, is a part of a memory device. In other embodiments, the memory cell is a part of an IC device. The memory cell, as shown, is a 2^{x} multi-bit memory cell. The multi-bit memory cell is similar to that described in FIGS. 1a-b. As such, common elements may not be described or described in detail.

The multi-bit memory cell includes a fin structure 420 disposed on a substrate in a first or x direction. The fin structure includes with transistors 110₁₋₂^{x}. Gates 130₁₋₂^{x} of the transistors are provided in contact with the fin structure. The gates, for example, include gate electrodes 136₁₋₂ₓ. The gate electrodes, for example, comprise elongated members. The gate electrodes, in one embodiment, traverse the fin structure in a second or y direction. The gate electrodes, as shown, completely wrap around the fin.

In one embodiment, a charge storage dielectric layer 134 is disposed on a top surface of the fin structure, separating upper portions of a gate electrode from the top of the fin structure and gate dielectric layers on fin sidewalls which separate lower portions of the gate electrodes from the fin structure. The charge storage dielectric layer may be provided with a storage protection layer on sides which contact the gate electrode layer.

A transistor includes first and second source/drain (S/D) regions in the fin structure adjacent to a gate. Adjacent transistors have first and second S/D regions which form a common S/D region 126, while the first S/D region of the first transistor 110₁ serves as the first cell terminal 122 and the second S/D region of the last transistor 110₂^{x} serves as the second cell terminal 124. The S/D regions are doped with first polarity type dopants. For example, the S/D regions are heavily doped with first polarity type dopants. Other dopant concentrations may also be useful.

First and second contact pads 421 and 423 may be provided at first and second ends of the fin structure. The contact pads provide additional surface area for contacts for coupling to the cell terminals. The contact pads, in one embodiment, are an integral part of the fin structure. For example, the contact pads have the same material as the fin structure and dopants of S/D regions of the transistors. For example, the fin structure is formed with the pad structures and doped at the same time as the S/D regions of the transistors are formed. Other configurations of fin structures, S/D regions and contact pads may also be useful.

In some embodiments, the S/D regions may be provided with lightly doped S/D extension regions. In some embodiments, the S/D extension profile may extend beneath the gate. Providing S/D extensions improves short channel effect. To facilitate forming S/D extension regions, gate sidewall spacers (not shown) may be provided. The gate sidewall spacers may be formed from a dielectric material, such as silicon oxide. Other types of spacer materials may also be useful. For example, S/D extensions are formed without the spacers and the main S/D regions are formed with the spacers. Other configurations of S/D extensions, S/D regions and spacers may also be useful.

The gates may be provided with gate contact pads (not shown). In one embodiment, a gate contact pad is provided at an end of a gate. Alternatively, gate contact pads are provided at ends of the gate. The contact pads provide additional surface area for contacts to couple to control lines. The contact pads, in one embodiment, are an integral part of the gate structure. For example, the contact pads have the same material as the gate. Other configurations of the gates and gate pads may also be useful.

FIGS. 5c-d show various views of another embodiment of a 2^{x} multi-bit memory cell 100. FIG. 5c shows a top view while FIG. 5d shows an isometric view of an embodiment of a memory cell of FIG. 5c. The memory cell, for example, is a part of a memory device. In other embodiment, the memory cell is a part of an IC device. As shown, the memory cell is similar to that described in FIGS. 5a-b. As such, common elements may not be described or described in detail.

The memory cell, as shown, includes gate electrodes 130₁₋₂^{x} of the first and second transistors 110₁₋₂^{x} which are disposed on first and second sides of the fin structure 420 and not over it. For example, a gate electrode includes first and second sub-gates which are separated by the fin sidewalls, charge storage dielectric layer and gate dielectric layers 150. The sub-gates, for example, have a top surface which is coplanar with a top surface of the charge storage dielectric layer 134. Providing first and second sub-gates allows the sub-gates to be separately biased.

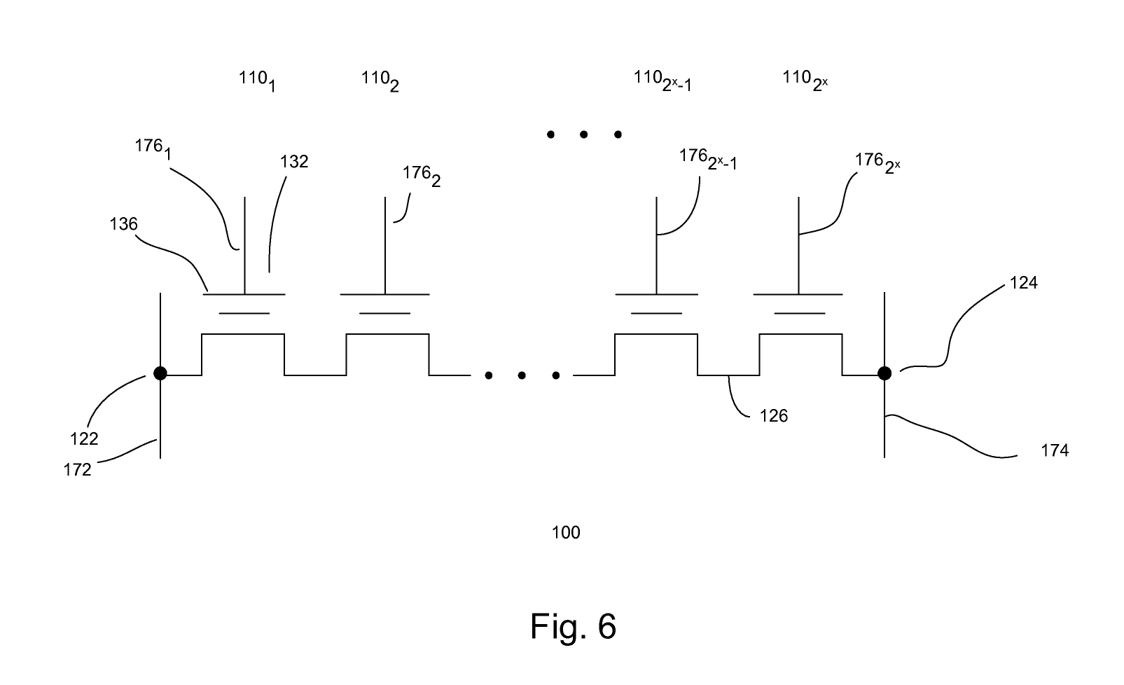

The operations of the memory cells as described in FIGS. 5a-d are illustrated in FIG. 6. FIG. 6 shows an embodiment of a multi-bit memory cell similar to that described in FIG. 2 except that the multi-bit memory cell includes 2^{x} number of bits, where x is any whole number greater than or equal to 1. As such, common elements may not be described or described in detail. The value of x, for example, may be about 3-4, corresponding to a byte or a word of data. In other embodiments, x may correspond to the number of bits per memory cell in a row of a memory array or a memory block. Other values of x may also be useful. In one embodiment, the 2^{x} bit memory cell is configured as a NAND type memory cell. Other types of memory cell configurations may also be useful. The multi-bit memory cell may be an n-type 2^{x} multi-bit memory cell. Providing a p-type 2^{x} multi-bit memory cell may also be useful.

Similar to FIG. 2, in FIG. 6, a transistor can serve as a MC and a SG interchangeably. For example, depending on which bit of the memory cell is accessed, one of the transistors may serve as the MC, and all the rest of the transistors may serve as the SGs. In one embodiment, some of the bits use the first terminal as a BL, and the other bits use the second terminal as a BL. For example, for an 8 bit memory cell, the first 4 bits may use the first terminal as a BL, and the second 4 bits may use the second terminal as a BL.

Appropriate signals or voltages may be applied to the different terminals of the memory cell, for example, via the SL, BL, CL and WL, to perform the desired memory access operations on the desired bit of the memory cell. Table 2a shows the various signals applied to the terminals of the memory cell, depending on the desired operation and bit to access.

TABLE 2A

| Oper- | SG/MC | SG/MC | BL | BL | SL | SL |
|---|---|---|---|---|---|---|
| ation | (Sel.) | (Unsel.) | (Sel.) | (Unsel.) | (Sel.) | (Unsel.) |
| Pro- | Vg, pgm | Vpass | Vd, pgm | Voff | Vs, pgm | Voff |
| gram | | | | | | |
| Erase | Vg, ers | Vpass | Vd, ers | Voff | Vs, ers | Voff |
| Read | Vg, read | Vpass | Vd, read | Voff | Vs, read | Voff |

Table 2b shows some embodiments of the values for the different signals applied to the terminals of an n-type memory cell and a p-type memory cell.

TABLE 2b

| Signal | n-type cell (V) | p-type cell (V) |
|---|---|---|
| Vpass | 3 | 3 |
| Voff | 0, float | 0, float |
| Vg, pgm | 5 | −5 |
| Vd, pgm | 6 | −6 |
| Vs, pgm | 0 | 0 |
| Vg, ers | −3 | 3 |
| Vd, ers | 6 | −6 |
| Vs, ers | 0 | 0 |
| Vg, read | 0 | 0 |
| Vd, read | 2 | −2 |
| Vs, read | 0 | 0 |

Providing signals of other voltages to the terminals of the memory cell may also be useful. For example, voltages of ±2 V from the exemplary values in table 2b for the signals may also be used.

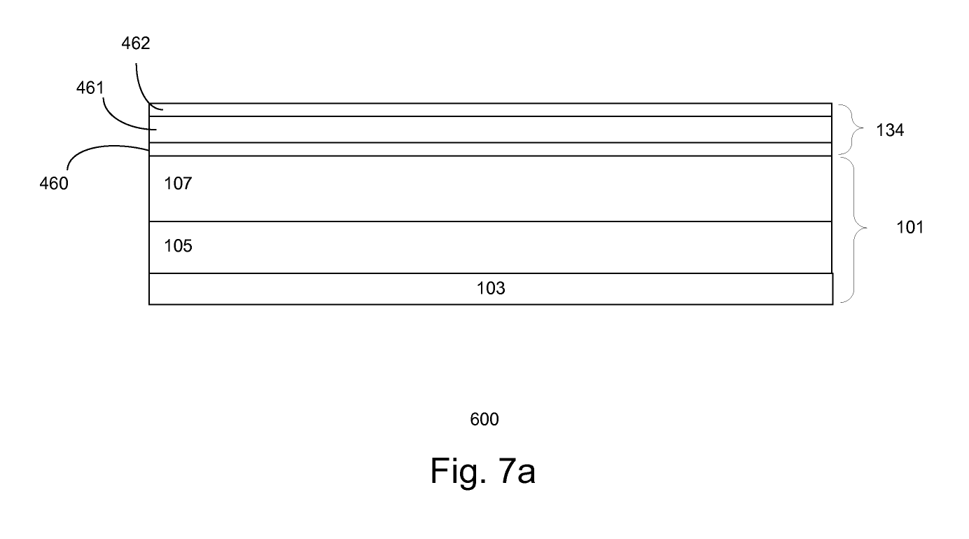

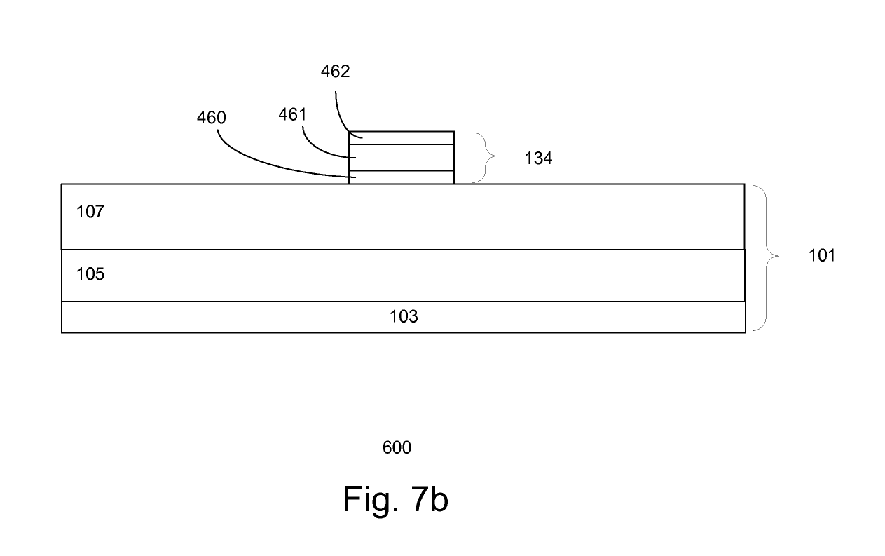

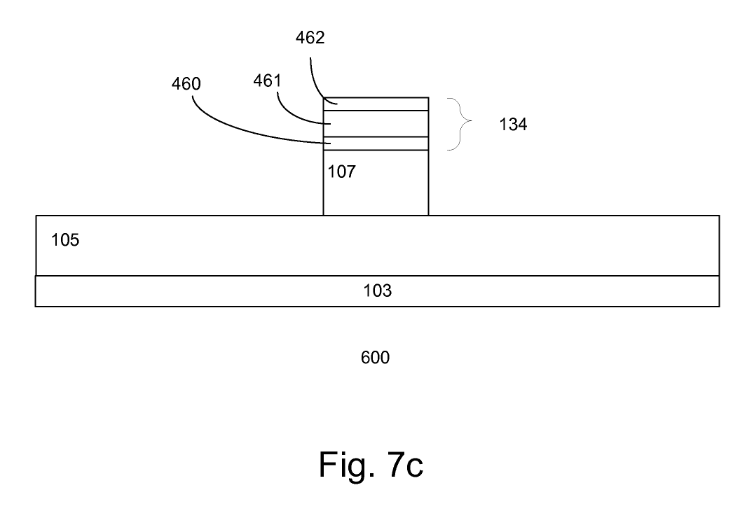

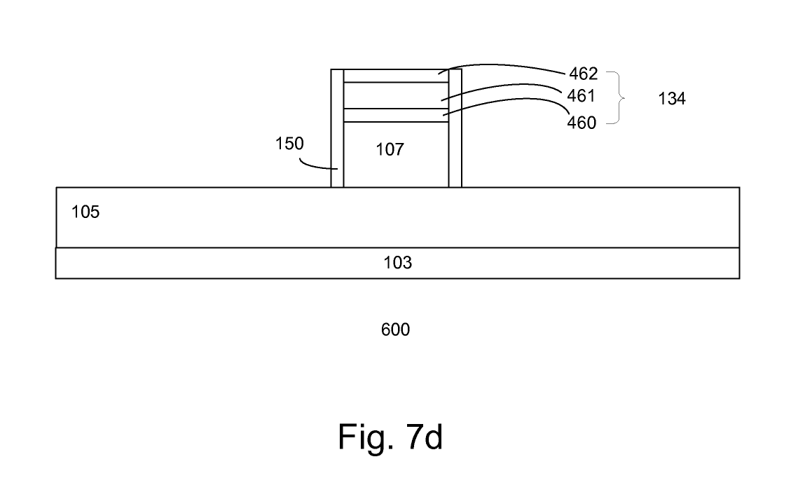

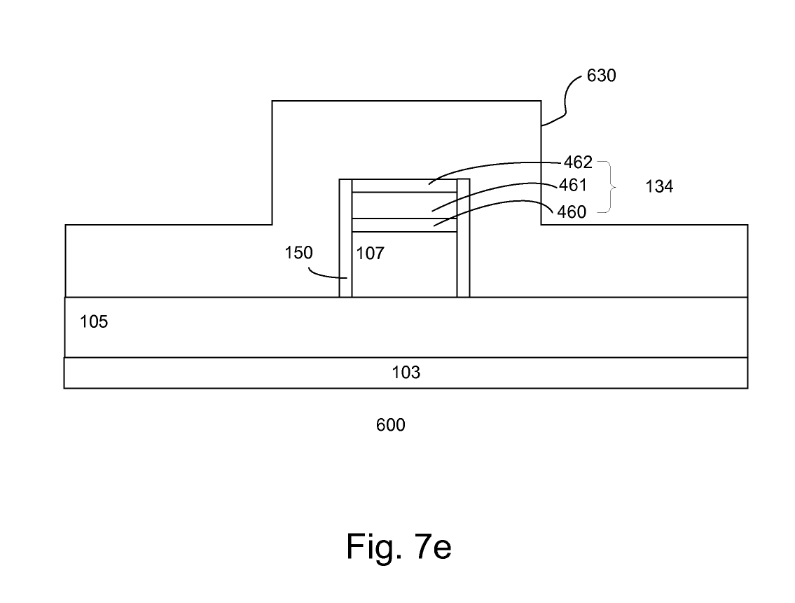

FIGS. 7a-d show cross-sectional views of an embodiment of a process 700 for forming a memory cell. The memory cell, for example, is a part of a memory device. In other embodiment, the memory cell is a part of an IC device. Referring to FIG. 7a, a substrate 101 is provided. In one embodiment, the substrate is a semiconductor-on-insulator substrate. A semiconductor-on-insulator substrate includes a surface semiconductor layer 107 separated from a crystalline bulk 103 by an insulator layer 105. The insulator layer, for example, may be a dielectric insulating material. The insulator layer, for example, is formed from silicon oxide, providing a buried oxide (BOX) layer. Other types of dielectric insulating materials may also be useful. The semiconductor-on-insulator substrate, for example, is a silicon-on-insulator (SOI) substrate. For example, the surface and bulk crystalline layers are single crystalline silicon. Other types of substrates, such as silicon-germanium (SiGe), germanium (Ge), gallium-arsenic (GaAs) or any other suitable semiconductor materials may also be useful for the semiconductor-on-insulator substrate. It is understood that the surface and bulk layers need not be the same material.

The substrate can be a lightly doped substrate. In one embodiment, at least the surface semiconductor layer is lightly doped. In one embodiment, the surface layer is lightly doped with p-type dopants. Providing other types of doped surface layers may also be useful. For example, the surface layer may be doped with n-type dopants and/or other dopant concentrations, including intrinsically doped, may also be used. Providing a doped bulk with the doped surface layer may also be useful.

In other embodiments, the substrate may be a bulk semiconductor substrate. For example, the bulk substrate is not a semiconductor-on-insulator substrate. The bulk substrate, for example, may be a silicon substrate. Alternatively, the substrate may be formed of other semiconductor materials, such as SiGe, Ge or GaAS. In one embodiment, the substrate is a lightly doped substrate. The substrate may be lightly doped with p-type dopants. Providing other types of substrates may also be useful. For example, the substrate may be doped with n-type dopants and/or other dopant concentrations, including intrinsically doped, may also be used.

In one embodiment, an implant may be performed to form a doped region which serves as a body of the memory cell. For example, the substrate is doped with second polarity type dopants. In one embodiment, the substrate is 10¹⁵-10¹⁸ doped with second polarity type dopants. The substrate may also be doped to form other doped regions for other devices. It is understood that in the case where the substrate is already provided with appropriate dopants to serve as a body of the memory cell, no doping is required to form the body. However, doping may still be required to form regions for other types of devices.

In one embodiment, a charge storage dielectric layer 134 is formed on the substrate. In one embodiment, as shown, a composite charge storage dielectric layer or stack is disposed on the substrate. The charge storage dielectric stack, for example, includes an oxide-nitride-oxide (ONO) sandwich 460, 461 and 462. Various techniques may be employed to form the ONO stack. For example, CVD and/or oxidation may be employed. The thickness of the first oxide layer 460 may be about 20-150 Å, the thickness of the second nitride layer 461 may be about 20-200 Å, and the thickness of the third oxide layer 462 may be about 30-250 Å. Other thicknesses and techniques or combinations of techniques may be employed to form the ONO stack. In one embodiment, the layers 460 and 462 include other types of materials, such as a high-k material or another composite dielectric stacks like ONO stacks. Other types of charge storage dielectric layers, such as oxide/a-Si/oxide, oxide/nanocrystal/oxide, oxide/nitride/Al₂O₃, or nanocrystal embedded in oxide and oxide-metal(high-K)-oxide stack may also be useful.

As shown in FIG. 7b, the charge storage dielectric layer 134 is patterned to define the shape of the fin. The patterning of the composite charge storage dielectric layer can be achieved, for example, by mask and etch techniques. For example, a patterned photoresist mask may be used as an etch mask for an anisotropic etch, such as a reactive ion etch (RIE), to pattern the charge storage stack. To improve lithographic resolution, an ARC can be provided beneath the photoresist. Other techniques for patterning the dielectric layer may also be useful. After patterning the substrate to form the charge storage stack, the mask, including the ARC layer, may be removed.

In one embodiment, the patterned charge storage dielectric layer may serve as a hard mask to pattern the surface substrate layer to form the fin, as shown in FIG. 7c. For example, an anisotropic etch, such as a RIE, patterns the surface layer to form the fin structure. As discussed, the fin structure may include the contact pads at ends of the fin structure. The resulting fin structure is disposed on a top of the BOX of the semiconductor substrate.

Referring to FIG. 7d, a gate dielectric layer 150 is formed on the sidewalls of the fin 420 and the charge storage dielectric layer 134. The gate dielectric layer, for example, is silicon oxide. In one embodiment, the gate dielectric layer is formed by oxidation. The oxidation forms an oxide layer on the sidewalls of the fin structure. The oxidation also forms a protection layer on sides of the charge storage dielectric layer. For example, the oxidation process forms an oxynitride layer on sides of the nitride layer. In other embodiments, the gate dielectric layer may be deposited on the substrate surface by, for example, CVD. The dielectric layer is anisotropically etched, such as by RIE, to remove horizontal portions, leaving vertical portions of sides of the fin structure and charge storage dielectric layers. In another embodiment, the dielectric layer on the substrate surface remains and is removed during a subsequent process, such as patterning of a gate electrode. The thickness of the dielectric layer may be about 40-200 Å. Other techniques to form the gate dielectric layer or forming other types of gate dielectric layer may also be useful. For example, other types of gate dielectric layer may include HfSiON, SiON or HfO₂.

In FIG. 7e, a gate electrode layer 630 is formed over the substrate, covering the gate dielectric layer 150 and the charge storage dielectric layer 134. The gate electrode layer, for example, is polysilicon. The gate electrode layer may be formed by, for example, CVD. The thickness of the gate electrode layer, for example, may be about 400-1000 Å. Other types of gate electrode layers, thicknesses or techniques for forming the gate electrode layer may also be useful. For example, the gate electrode layer may be a metal gate electrode layer, such as TaN and TiN.

The gate electrode layer is patterned to form a gate which traverses the fin 420. The gate electrode layer may be patterned, for example, using a soft mask, such as photoresist. To improve lithographic resolution, an ARC can be provided beneath the photoresist. The photoresist may be patterned by exposing it with an exposure source through a reticle. The exposed photoresist is developed, transferring the pattern of the reticle to the photoresist. The patterned photoresist serves as an etch mask to pattern the gate electrode layer to form gates traversing the fin structure. Patterning the gate electrode layer can be achieved using, for example, an anisotropic etch, such as a RIE. An RIE may pattern the ARC using the photoresist mask, followed by an RIE to pattern the gate electrode layer. Other techniques for patterning the gate electrode layer may also be useful. In one embodiment, the gate electrode layer is patterned to form first and second gates for a dual bit memory cell, as described in FIGS. 1a-b. Alternatively, the gate electrode layer is patterned to form a 2^{x} multi-bit memory cell, as described in FIGS. 5a-b. After patterning the substrate to form the gate stack, the mask, including the ARC layer, may be removed.

The gate electrode may be doped to reduce resistance, adjust V_{T}, adjust work function or a combination thereof. The type of dopants and dopant concentration may be appropriately selected based on the design requirements. The gate layer may be in situ doped during formation or doped by ion implantation after the formation of the gate electrode layer.

The process continues, for example, to form S/D regions in the fin structure adjacent to the non-adjacent sides of the gates or non-adjacent sides of the first and last gates. The S/D regions comprise first polarity type dopants. The S/D regions are formed by ion implantation. In one embodiment, the S/D regions are formed by self-aligned ion implantation with the gate as the implantation mask. In one embodiment, lightly doped S/D extension regions are formed prior to forming the S/D regions. The lightly doped extension regions are formed prior to formation of gate sidewall spacers and the S/D regions are formed after formation of the gate sidewall spacers. The process parameters of the implantation, such as dose and energy, may be appropriately selected based on design requirements. The process further continues to form interconnects and other processes to complete the device, such as passivation, dicing, and packaging. Depending on the type of device, other processes may be included.

In the case where a bulk substrate instead of a semiconductor-on-insulator substrate is used, the substrate may be etched to form a fin structure using the charge storage dielectric layer as a hard mask, as described in FIG. 7c. The etch, for example, is a timed etch to produce a fin structure with an initial desired height H₁. After the fin structure is formed, a dielectric layer, such as silicon oxide, is formed on the substrate. Other types of dielectric layers may also be useful. The thickness of the dielectric layer T_{d} is sufficient to serve as an insulation region from the substrate surface. The thickness T_{d}, for example, is about 500-5000 Å. Other types of thicknesses may also be useful. The thickness T_{d} defines a final height H_{F} of the fin. For example, H_{F} is equal to H₁-T_{d}.

In one embodiment, the dielectric layer is deposited non-conformally. For example, the dielectric covers the substrate surface without covering upper portions of the fin. In one embodiment, the dielectric layer may be formed by e-beam deposition.

In another embodiment, a dielectric layer is deposited conformally over the substrate, filling the spaces between fin structures as well as covering them. The dielectric layer may be formed by CVD. Excess dielectric material is removed by a planarization process. In one embodiment, the excess material may be removed by CMP. Other types of planarization processes may also be useful. The CMP, for example, may use the charge storage dielectric layer as a CMP stop. For example, the CMP forms a coplanar surface with the dielectric layer and charge storage dielectric layer. In the case where the top layer of the charge storage dielectric layer is the same as dielectric layer, the nitride layer may serve as the CMP stop. After CMP, a dry or wet etch may be performed to reduce the dielectric layer to a desired thickness T_{d}.

The process continues to form a gate dielectric, as described in FIG. 7d. If the top oxide layer of the charge storage dielectric layer is removed, it may be reformed during the process of forming the gate dielectric. For example, the process forms a top oxide of the charge storage dielectric layer, storage protection layer and gate dielectric on sides of the fin structure. The process continues as described from FIG. 7e and onwards.

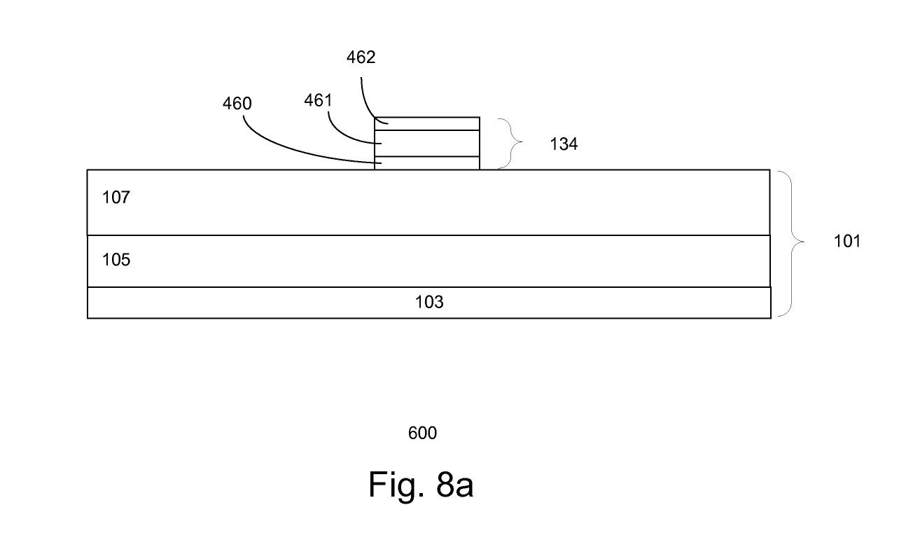

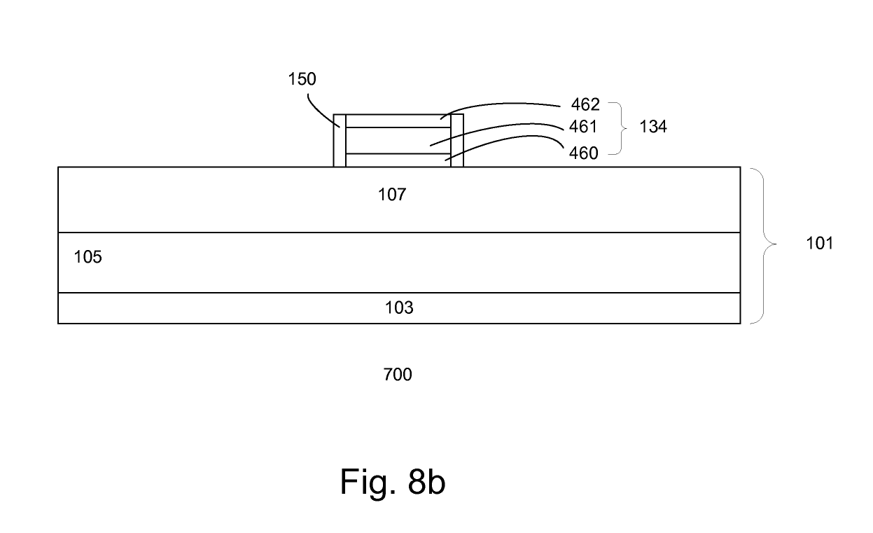

FIGS. 8a-b show cross-sectional views of another embodiment of a process 800 for forming a memory cell. The memory cell, for example, is a part of a memory device. In other embodiment, the memory cell is a part of an IC device. The process is similar to that described in FIGS. 7a-e. As such, common elements may not be described or described in detail.

Referring to FIG. 8a, the structure shown is at the stage of processing shown in FIG. 7b. For example, the composite charge storage dielectric layer 134 is patterned to define the shape of the fin.

As shown in FIG. 8b, a dielectric layer 150 is formed on the sidewalls of the charge storage dielectric layer 134. The dielectric layer, for example, is silicon oxide. In one embodiment, the gate dielectric layer is formed by oxidation. The oxidation forms a protection layer on sides of the charge storage dielectric layer. For example, the oxidation process forms a protection layer on sides of the nitride layer. In other embodiments, the protection dielectric layer may be deposited on the substrate surface by, for example, CVD. The dielectric layer is anisotropically etched, such as by RIE, to remove horizontal portions, leaving vertical portions of sides of the charge storage dielectric layer to serve as a protection layer. The thickness of the dielectric layer may be about 40-200 Å. Other techniques to form the protection layer or forming other types of protection layer may also be useful.

The process continues to form the fin by patterning the surface substrate layer using the charge storage dielectric layer with the dielectric layer 150 as a hard mask. After defining the fin, gate dielectric can be grown or deposited on the sides of the fins. The process continues, for example, as described in FIG. 7e.

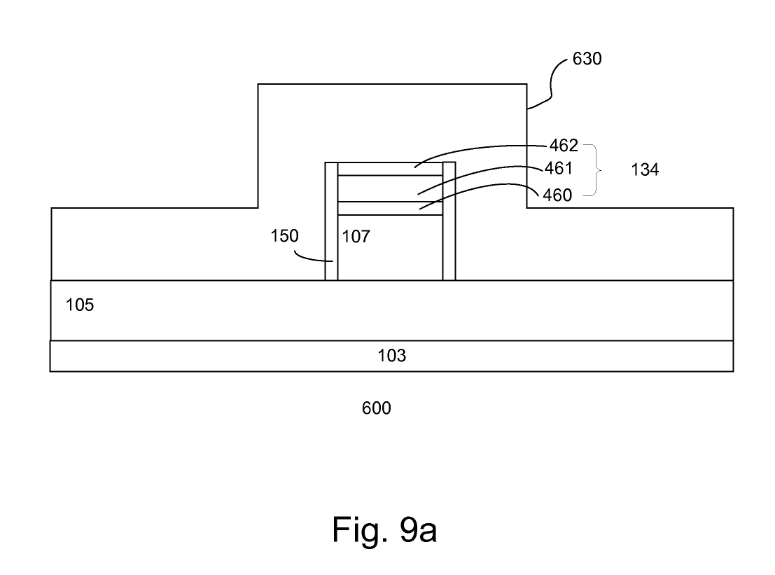

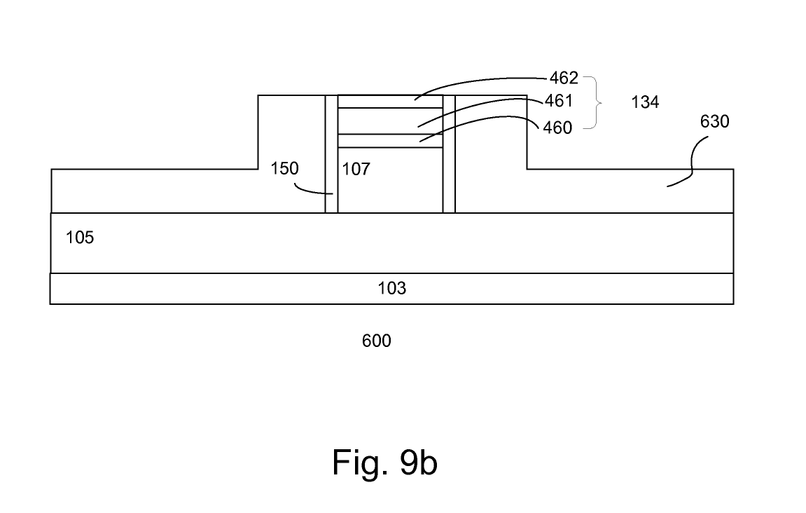

FIGS. 9a-b show cross-sectional views of another embodiment of a process 900 for forming a memory cell. The memory cell, for example, is a part of a memory device. In other embodiment, the memory cell is a part of an IC device. The process is similar to that described in FIGS. 7a-e. As such, common elements may not be described or described in detail.

Referring to FIG. 9a, the structure shown is at the stage of processing shown in FIG. 7e. For example, a gate electrode layer 630 is formed over the substrate, covering the gate dielectric layer 150 and the charge storage dielectric layer 134.

In one embodiment, as shown in FIG. 9b, excess gate electrode material is removed by a planarization process. In one embodiment, the excess material is removed by CMP. Other types of planarization processes may also be useful. The CMP, for example, may use the charge storage dielectric layer as a CMP stop. For example, the CMP forms a coplanar surface with the top of the charge storage dielectric layer. In one embodiment, a gate is a multiple sub-gates with first and second sub-gates.

Alternatively, gates with multiple sub-gates, such as first and second sub-gates, may be formed after the gates are formed. For example, after the gates and S/D regions are formed, as described in FIG. 7e, a dielectric layer is deposited on the substrate, filling the spaces between the gates as well as covering the gates. The dielectric layer, for example, serves as a part of an interlevel dielectric layer. After the dielectric layer is formed, the substrate is planarized. For example, the substrate is planarized by CMP. The CMP removes excess dielectric material as well as the portion of the gate above the charge storage layers. This produces a coplanar surface between the charge storage layers and sub-gates.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A device comprising:
a substrate; and
a fin structure disposed on the substrate, the fin structure serves as a common body of n transistors, the transistors comprise separate charge storage layers and gate dielectric layers, the charge storage layers disposed over a top surface of the fin structure and the gate dielectric layers disposed on sidewalls of the fin structure, wherein n=2^{x}, x is a whole number greater or equal to 1, wherein a transistor can interchange between a select transistor and a storage transistor.

2. The device in claim 1 wherein the device is a multi-bit memory cell with n number of bits.

3. The device in claim 1 wherein the transistor comprises n number of gates, a gate can interchange between a select gate and a control gate.

4. The device in claim 3 wherein the gate comprises a gate electrode which wraps around the fin structure.

5. The device in claim 3 wherein the gate comprises first and second sub-gates which are separated by sidewalls of the fin structure.

6. The device in claim 3 comprises doped regions in the fin structure adjacent to the gate.

7. The device in claim 1 wherein the charge storage layers comprise an oxide-nitride-oxide stack.

8. A method of forming a device comprising:
providing a substrate; and
forming a fin structure disposed on the substrate, the fin structure serves as a common body of n transistors, the transistors comprise separate charge storage layers and gate dielectric layers, the charge storage layers disposed over a top surface of the fin structure and the gate dielectric layers disposed on sidewalls of the fin structure, wherein n=2^{x}, x is a whole number greater or equal to 1, wherein a transistor can interchange between a select transistor and a storage transistor.

9. The method in claim 8 wherein the device is a multi-bit memory cell with n number of bits.

10. The method in claim 8 wherein the transistor comprises n number of gates, a gate can interchange between a select gate and a control gate.

11. The method in claim 10 wherein the gate comprises a gate electrode which wraps around the fin structure.

12. The method in claim 10 wherein the gate comprises first and second sub-gates which are separated by sidewalls of the fin structure.

13. The method in claim 8 comprises forming protection layers on sidewalls of the charge storage layers.

14. The method in claim 13 wherein the charge storage layers comprise an oxide-nitride-oxide stack.

15. The method in claim 8 comprises forming doped regions in the fin structure adjacent to the gate.

16. The method in claim 15 wherein the doped regions comprises source/drain regions which are coupled to a select line and a bitline.

17. A multi-bit device comprising:
a substrate;
a fin structure disposed on the substrate, the fin structure serves as a common body of n transistors which are coupled in series between first and second cell terminals, the transistors comprise separate charge storage layers and gate dielectric layers, the charge storage layers disposed over a top surface of the fin structure and the gate dielectric layers disposed on sidewalls of the fin structure, wherein n=2^{x}, x is a whole number greater or equal to 1, wherein a transistor can interchange between a select transistor and a storage transistor;
wherein a transistor comprises first and second source/drain terminals, first source/drain terminal of the first transistor is coupled to the first cell terminal, second source/drain terminal of the last transistor is coupled to the second cell terminal, second source/drain terminal and first source/drain terminal of adjacent transistors form a common source/drain region in the fin structure.

18. The multi-bit device in claim 17 wherein a transistor comprises n number of gates, a gate can interchange between a select gate and a control gate.

19. The multi-bit device in claim 18 wherein the transistor comprises a gate electrode which wraps around the fin structure.

20. The multi-bit device in claim 18 wherein the gate comprises first and second sub-gates which are separated by sidewalls of the fin structure.
